(19) United States
(12) Patent Application Publication
(10) Pub. No.: US 2008/0226941 A1
(43) Pub. Date: Sep. 18, 2008

(54) Solvent Mixtures For Organic Semiconductors

(75) Inventors: Heinrich Becker, Hofheim (DE); Susanne Heun, Bad Soden (DE)

Correspondence Address: CONNOLLY BOVE LODGE & HUTZ, LLP, P O BOX 2207, WILMINGTON, DE, 19899, US

(73) Assignee: Merck Patent GmbH, Darmstadt (DE)

(21) Appl. No.: 12/063,969

(22) PCT Filed: Jul. 25, 2006
(86) PCT No.: PCT/EP2006/007295

§ 371 Date: Feb. 15, 2008

(30) Foreign Application Priority Data
Aug. 18, 2005 (DE) 10 2005 039 528.7

(51) Int. Cl. H01B 1/12; H01L 51/00

(52) U.S. Cl. 428/690; 252/500

(57) ABSTRACT

The present invention relates to solutions of at least one organic semiconductor in at least one organic solvent with at least one aliphatic or cycloaliphatic alkene, and to the use thereof for the production of layers of organic semiconductors on substrates, in particular for the electronics industry.

The use of organic semiconductors as functional materials has been reality for some time or is expected in the near future in a number of different applications which can be ascribed to the electronics industry in the broadest sense. The development of organic transistors (O-TFTs, O-FETs), organic integrated circuits (O-ICs), organic field-quench devices (O-FQDs), organic light-emitting transistors (O-LFTs), light-emitting electrochemical cells (LECs) and organic solar cells (O-SCs) has already progressed a very long way at the research stage, meaning that a market introduction can be expected within the next few years. In the case of organic electroluminescent devices (OLEDs, PLEDs), the market introduction has already taken place. In spite of all advances, however, significant improvements are still necessary in order to make these displays a true competitor to the liquid-crystal displays (LCDs) which currently dominate the market.

Solutions of organic semiconductor materials, such as, for example, charge-transport polymers and various light-emitting materials, can be employed for various printing processes and spin-coating processes. At present, work is principally being carried out on ink-jet printing (IJP) processes owing to the good controllability, the achievable resolution and the great variability. In principle, however, other printing processes, such as, for example, offset printing, transfer printing or gravure printing processes, are also suitable. On the other hand, corresponding colour displays can also be produced by photolithographic processes. Here, area-coating processes, for example spin coating, can then be used, as for monochromatic display devices. For all these possibilities, suitable solutions are required which on the one hand are suitable for printing or for application by area-coating processes, but on the other hand also do not impair the properties of the PLEDs.

It has been observed that layers of organic semiconductors which have been produced in air have worse electronic properties, in particular lower efficiency of the light emission and worse operational stability, than those which have been produced under a protective-gas atmosphere. It is thought that the trace gases, for example ozone, present in the air are responsible for this observation. Thus, a comparison of the maximum efficiency of various polymers on exposure to 50 ppb of ozone shows that the maximum efficiency drops significantly due to the influence of the ozone. It is therefore obvious to assume that atmospheric trace gases of any type can have adverse effects on the electro-optical properties of the solutions.

Processes for the production of layers of organic semiconductors which are not carried out under a protective-gas atmosphere therefore result in a decrease in the maximum efficiency of light emission and thus also in worse displays or light sources. On the other hand, the production of layers under a protective-gas atmosphere requires significantly greater technical complexity, meaning that it would be sensible to be able to produce layers in air.

Surprisingly, it has now been found that the addition of at least one alkene to the solution of the organic semiconductor material during production of layers in air results in a significant improvement in the efficiencies of the materials.

WO 01/16251 describes solutions of organic semiconductors where the solvent or solvent mixture comprises at least one terpene and/or a polyalkylated aromatic compound. The examples here disclose solvent mixtures which consist of polyalkylated aromatic compounds and terpenes in the ratio 3:1. A mixture having such a high content of terpenes has the crucial disadvantage that many organic semiconductors are insoluble in this solvent mixture, meaning that the solvent mixtures disclosed are possibly suitable for the polymer blend used therein, but not for a multiplicity of other organic semiconductors.

The present invention relates to single-phase, liquid compositions (solutions) comprising
at least one organic semiconductor,
at least one organic solvent for the organic semiconductor, and
at least one aliphatic or cycloaliphatic alkene,
   which are characterised in that the proportion of the alkene is between 0.01 and 20% by weight, based on the solvent or solvent mixture.

For the purposes of the present application text, solutions are liquid, homogeneous mixtures of solid substances in liquid solvents in which the solids are in molecularly disperse dissolved form, i.e. the majority of the molecules of the solid are actually dissolved and are not in the form of aggregates or nano- or microparticles.

For the purposes of this invention, an organic solvent is intended to be taken to mean organic substances which are able to bring other substances into solution by physical means without the dissolving or dissolved substance changing chemically during the dissolution process. The solubility of the organic semiconductor in the organic solvent or in the organic solvent mixture at room temperature and atmospheric pressure here is preferably at least 1 g/l, particularly preferably at least 3 g/l and in particular at least 5 g/l, with formation of a clear, flowable solution.

For the purposes of the present invention, room temperature is 20° C., and atmospheric pressure means 1013 mbar.

The present invention furthermore relates to the use of the solutions according to the invention for producing layers of organic semiconductors on a substrate.

A preferred embodiment here is the use of printing processes for the production of the organic semiconductor layers. Particular preference is given here to the use of ink-jet printing (IJP) processes.

A further preferred embodiment is the use of area-coating processes for the production of the organic semiconductor layers, in particular the use of spin coating.

The present invention likewise relates to layers of the organic semiconductors, produced using the solutions according to the invention.

The invention furthermore relates to organic electronic devices, preferably organic field-effect transistors (O-FETs), organic thin-film transistors (O-TFTs), organic integrated circuits (O-ICs), organic field-quench devices (O-FQDs), organic light-emitting transistors (O-LETs), light-emitting electrochemical cells (LECs), organic solar cells (O-SCs) or organic laser diodes (O-lasers), but in particular organic and polymeric light-emitting diodes (OLEDs, PLEDs), containing at least one layer according to the invention.

Layers of the organic semiconductors known per se have already been described in the literature. The layers produced from the solutions according to the invention in air exhibit improved electronic properties compared with the layers described to date. In particular, higher luminous efficiencies are obtained with the layers produced from the solutions according to the invention than in accordance with the prior art if the layers have been produced in air.

For the purposes of this application, organic semiconductors are low-molecular-weight, oligomeric, dendritic, linear or branched and in particular polymeric organic or organometallic compounds or mixtures of compounds which, as a solid or layer, have semiconducting properties, i.e. in which the energy gap between conduction and valence bands is between 1.0 and 3.5 eV.

The organic semiconductor used here is either a pure component or a mixture of two or more components, at least one of which must have semiconducting properties. In the case of the use of mixtures, however, it is not necessary for each component to have semiconducting properties. Thus, for example, inert low-molecular-weight compounds can be used together with semiconducting polymers. It is likewise possible to use non-conducting polymers, which serve as inert matrix or binder, together with one or more low-molecular-weight compounds or further polymers having semiconducting properties. For the purposes of this application, the potentially admixed non-conducting component is taken to mean an electro-optically inactive, inert, passive compound.

Preference is given to solutions of polymeric organic semiconductors, which optionally comprise further admixed substances. The molecular weight M_{w} of the polymeric organic semiconductor is preferably greater than 10,000 g/mol, particularly preferably between 50,000 and 1,000,000 g/mol and in particular between 100,000 and 500,000 g/mol. For the purposes of the present invention, polymeric organic semiconductors are taken to mean, in particular,
(i) the substituted poly-p-arylenevinylenes (PAVs) disclosed in EP 0443861, WO 94/20589, WO 98/27136, EP 1025183, WO 99/24526, DE 19953806 and EP 0964045 which are soluble in organic solvents,
(ii) the substituted polyfluorenes (PFs) disclosed in EP 0842208, WO 00/22027, WO 00/22026, DE 19846767, WO 00/46321, WO 99/54385 and WO 00155927 which are soluble in organic solvents,
(iii) the substituted polyspirobifluorenes (PSFs) disclosed in EP 0707020, WO 96/17036, WO 97/20877, WO 97/31048, WO 97/39045 and WO 031020790 which are soluble in organic solvents,
(iv) the substituted poly-para-phenylenes (PPPs) or -biphenylenes disclosed in WO 92/18552, WO 95/07955, EP 0690086, EP 0699699 and WO 03/099901 which are soluble in organic solvents,
(v) the substituted polydihydrophenanthrenes (PDHPs) disclosed in WO 05/014689 which are soluble in organic solvents,
(vi) the substituted poly-trans-indenofluorenes and poly-cis-indenofluorenes (PIFs) disclosed in WO 04/041901 and WO 04/113412 which are soluble in organic solvents,
(vii) the substituted polyphenanthrenes disclosed in the unpublished application DE 102004020298.2 which are soluble in organic solvents,
(viii) the substituted polythiophenes (PTs) disclosed in EP 1028136 and WO 95/05937 which are soluble in organic solvents,
(ix) the polypyridines (PPys) disclosed in T. Yamamoto et at., J. Am. Chem. Soc. 1994, 116, 4832 which are soluble in organic solvents,
(x) the polypyrroles disclosed in V. Gelling et at., Polym. Prepr. 2000, 41, 1770 which are soluble in organic solvents,
(xi) substituted, soluble copolymers having structural units from two or more of classes (i) to (x), as described, for example, in WO 02/077060,
(xii) the conjugated polymers disclosed in Proc. of ICSM '98, Part I & II (in: Synth. Met 1999, 101/102) which are soluble in organic solvents,
(xiii) substituted and unsubstituted polyvinylcarbazoles (PVKs), as disclosed, for example, in R. C. Penwell et al., J. Polym. Sci., Macromol Rev. 1978, 13, 63-160,
(xiv) substituted and unsubstituted triarylamine polymers, as disclosed, for example, in JP 2000/072722,
(xv) substituted and unsubstituted polysilylenes and polygermylenes, as disclosed, for example, in M. A. Abkowitz and M. Stolka, Synth. Met. 1996, 78, 333, and
(xvi) soluble polymers containing phosphorescent units, as disclosed, for Us example, in EP 1245659, WO 03/001616, WO 03/018653, WO 03/022908, WO 03/080687, EP 1311138, WO 031102109, WO 04/003105, WO 04/015025, DE 102004032527.8 and some of the specifications already cited above.

Preference is furthermore also given to solutions of non-conducting, electronically inert polymers (matrix polymers) which comprise admixed low-molecular-weight, oligomeric, dendritic, linear or branched and/or polymeric organic and/or organometallic semiconductors.

The solutions may comprise further additives which are able to change, for example, the wetting properties. Additives of this type are described, for example, in WO 03/019693.

The solutions according to the invention comprise between 0.01 and 20% by weight, preferably between 0.1 and 15% by weight, particularly preferably between 0.2 and 10% by weight and in particular between 0.25 and 5% by weight, of the organic semiconductor or the corresponding blend. The percent data relate to 100% of the solvent or solvent mixture.

The viscosity of the solutions according to the invention is variable. However, certain coating techniques require use of certain viscosity ranges. Thus, a range from about 4 to 25 mPa·s is generally advantageous for coating by IJP. For area coatings (such as spin coating), viscosities in the range from about 5 to 40 mPa·s may be advantageous. For other printing processes, for example gravure printing processes or screen printing, however, a significantly higher viscosity, for example in the range from 20 to 500 mPa·s, may well also give rise to advantages. The viscosity can be adjusted through the choice of the suitable molecular-weight range of the organic semiconductor or matrix polymer and through the choice of a suitable concentration range and the choice of solvents.

The surface tension of the solutions according to the invention is initially not restricted. Through the use of corresponding solvent mixtures, however, it will preferably be in the range from 20 to 60 dyn/cm, particularly preferably in the range from 25 to 50 dyn/cm and in particular in the range from 25 to 40 dyn/cm.

Preferred solvents are mono- or polysubstituted aromatic solvents, in particular substituted benzenes, naphthalenes, biphenyls and pyridines. Preferred substituents are alkyl groups, which may also be fluorinated, halogen atoms, preferably chlorine and fluorine, cyano groups, alkoxy groups, dialkylamino groups, preferably those having not more than 4 C atoms, or also ester groups. Particularly preferred substituents are fluorine, chlorine, cyano, methoxy, ethoxy, methyl, ethyl, propyl, isopropyl, trifluoromethyl, methylcarboxylate and/or ethylcarboxylate, it also being possible for a plurality of different substituents, which can in turn form one or more rings with one another, to be present. However, non-aromatic solvents, such as, for example, formic acid derivatives, N-alkylpyrrolidiones or high-boiling ethers, are also suitable as solvents.

Particular preference is given to solutions according to the invention comprising, as solvents, one or more solvents selected from 3-fluorobenzo-trifluoride, benzotrifluoride, dioxane, trifluoromethoxybenzene, 4-fluoro-benzotrifluoride, 3-fluoropyridine, toluene, 2-fluorotoluene, 2-fluorobenzotrifluoride, 3-fluorotoluene, pyridine, 4-fluorotoluene, 2,5-difluorotoluene, 1-chloro-2,4-difluorobenzene, 2-fluoropyridine, 3-chlorofluorobenzene, 1-chloro-2,5-difluorobenzene, 4-chlorofluorobenzene, chlorobenzene, 2-chlorofluorobenzene, p-xylene, m-xylene, o-xylene, 2,6-lutidine, 2-fluoro-m-xylene, 3-fluoro-o-xylene, 2-chlorobenzotrifluoride, dimethylformamide, 2-chloro-6-fluorotoluene, 2-fluoroanisole, anisole, 2,3-dimethylpyrazine, bromobenzene, 4-fluoroanisole, 3-fluoroanisole, 3-trifluoromethylanisole, 2-methylanisole, phenetol, benzodioxole, 4-methylanisole, 3-methyl-anisole, 4-fluoro-3-methylanisole, 1,2-dichlorobenzene, 2-fluorobenzo-nitrile, 4-fluoroveratrol, 2,6-dimethylanisole, aniline, 3-fluorobenzonitrile, 2,5-dimethylanisole, 2,4-dimethylanisole, benzonitrile, 3,5-dimethylanisole, N,N-dimethylaniline, 1-fluoro-3,5-dimethoxybenzene, phenyl acetate, N-methylaniline, methyl benzoate, N-methylpyrrolidone, morpholine, 1,2-dihydronaphthalene, 1,2,3,4-tetrahydronaphthalene, 3,4-dimethylanisole, o-tolunitrile, veratrol, ethyl benzoate, N,N-diethylaniline, propyl benzoate, 1-methyinaphthalene, butyl benzoate, 2-methylbiphenyl, 2-phenylpyridine and 2,2′-bitolyl.

Also suitable are mixtures of the above-mentioned solvents with solvents in which the organic semiconductor has low solubility, as described in DE 102004023276.8, such as, for example, (cyclo)aliphatic alcohols, straight-chain, branched or cyclic alkanes, preferably having more than five C atoms, ethers, ketones, carboxylic acid esters or mono- or polysubstituted aromatic solvents, in particular substituted benzenes, naphthalenes and pyridines which are substituted by long alkyl or alkoxy substituents.

Furthermore particularly suitable are mixtures of a plurality of solvents in which the organic semiconductor has various solubilities and which have certain conditions for the respective boiling points of the solvents, as described, for example, in DE 102004007777.0.

The above-mentioned solvents cannot lay claim to completeness. The preparation of a solution according to the invention is readily possible for the person skilled in the art without an inventive step, even with other solvents not explicitly mentioned here.

The solutions according to the invention comprise—as described above—at least one organic semiconductor, at least one solvent for the organic semiconductor and at least one alkene, and optionally further additives.

The solutions according to the invention comprise in the solution between 0.01 and 20% by weight of a suitable alkene, preferably between 0.1 and 10% by weight, particularly preferably between 0.5 and 5% by weight, of the alkene or a mixture of two or more alkenes. The proportion of the alkene here is based on 100% of the solvent or solvent mixture.

It is preferred here for the boiling point of the alkenes to be below 250° C., particularly preferably below 200° C. In the case of higher-boiling alkenes, they can only be removed completely with difficulty and with considerable technical complexity after film formation.

An appropriate lower limit for the boiling point of the alkene is regarded as 50° C. A lower boiling point makes reproducible preparation of the solutions or layers difficult since the alkene is then too volatile.

Suitable as added alkene are cycloaliphatic and aliphatic alkenes. These may each have one or more double bonds.

The added alkenes are preferably liquid at room temperature and preferably contain 5 to 15 carbon atoms.

It is assumed that the added alkenes react with the trace gases from the air, in particular with ozone, and thus scavenge these and prevent harmful reactions with the organic semiconductor. The alkenes are therefore preferably selected in such a way that the reaction products thereof after the reaction with ozone, i.e., in particular, the corresponding aldehydes, are volatile and preferably contain 1 to 10 carbon atoms.

A selection of preferred alkenes as constituent of the solutions according to the invention is given in Table 1 below.

TABLE 1
Preferred alkenes for the preparation of solutions according to the
invention

| | | Boiling point |
|---|---|---|
| Alkene | CAS Number | [° C.] |
| 2,3-Dimethyl-2-butene | 563-79-1 | |
| 4-Methyl-1-pentene | 691-37-2 | 53-54 |
| 2,3-Dimethyl-1-butene | 563-78-0 | 56 |
| 1,5-Hexadiene | 592-42-7 | 60 |
| 1-Hexene | 592-41-6 | 62-64 |
| 1-Methyl-1-cyclopentene | 693-89-0 | 72 |
| 1,3-Cyclohexadiene | 592-57-4 | 80 |
| Cyclohexene | 110-83-8 | 83 |
| Trans,trans-2,4-hexadiene | 592-45-0 | 83 |
| 1,4-Cyclohexadiene | 628-41-1 | 88-89 |
| 2-Methyl-1-hexene | 6092-02-6 | 91 |
| 1-Heptene | 592-76-7 | 94 |
| 2,4,4-Trimethyl-1-pentene | 107-39-1 | 98-105 |
| 1,7-Octadiene | 3710-30-3 | 116-118 |
| 1-Octene | 111-66-0 | 121 |
| Trans-4-octene | 14850-23-8 | 122 |
| Trans-2-octene | 13389-42-9 | 122-123 |
| 2,5-Dimethyl-2,4-hexadiene | 764-13-6 | 134 |
| 1,3-Cyclooctadiene | 1700-10-3 | 142-144 |
| Styrene | 100-42-5 | 145-146 |
| Dicyclopentadiene | 77-73-6 | 166 |
| 1,9-Decadiene | 1647-16-1 | 169 |
| 1-Decene | 872-05-9 | 169-171 |
| 1-Dodecene | 112-41-4 | 213-216 |
| Cyclododecene | 1501-82-2 | |
| 1-Tridecene | 2437-56-1 | 232-233 |
| Cis,trans,trans-1,5,9-cyclododecatriene | 706-31-0 | 239-241 |

Preferred alkenes are thus 2,3-dimethyl-2-butene, 4-methyl-1-pentene, 2,3-dimethyl-1-butene, 1,5-hexadiene, 1-hexene, 1-methyl-1-cyclopentene, 1,3-cyclohexadiene, cyclohexene, trans,trans-2,4-hexadiene, 1,4-cyclohexadiene, 2-methyl-1-hexene, 1-heptene, 2,4,4-trimethyl-1-pentene, 1,7-octadiene, 1-octene, trans-4-octene, trans-2-octene, 1,3-cyclooctadiene, styrene, dicyclopentadiene, 1,9-decadiene, 1-decene, 1-dodecene, cyclododecene, 2,5-dimethyl-2,4-hexadiene, 1-tridecene and cis,trans,trans-1,5,9-cyclododecatriene.

These alkenes listed cannot lay claim to completeness. The preparation of a solution according to the invention is readily possible for the person skilled in the art without an inventive step, even with other alkenes not explicitly mentioned here.

It may also be appropriate to use a mixture of a plurality of alkenes. Thus, it may be entirely appropriate and preferred in each case to use two or more alkenes since this enables the optimisation of the solution properties to be achieved more simply in some cases, compared with the case where only one alkene is used.

It may furthermore also be appropriate to add further additives, as described, for example, in WO 03/019693, in addition to the organic semiconductor or blend.

For the preparation of the solutions, the organic semiconductor or blend is dissolved in the desired concentration in the desired solvent or solvent mixture together with the desired alkene or alkene mixture. It may be appropriate to accelerate the dissolution process, for example by heating and/or stirring. Aggregates of the organic semiconductor or matrix polymer can also be comminuted here, for example through external mechanical action, for example by ultrasound, as described in WO 03/019694. It may furthermore be appropriate firstly to dissolve the organic semiconductor or blend in the desired solvent or solvent mixture and only then to add the alkene. Likewise, it may furthermore prove appropriate to filter the solutions before use in order to free them from, for example, relatively small amounts of crosslinked constituents and/or dust particles. The solutions are preferably prepared under a protective-gas atmosphere, in particular under nitrogen or argon, but the addition of alkene here also already results in lower air sensitivity of the solutions.

If it is intended that the production of electroluminescent devices should then nevertheless be carried out in air, the solutions according to the invention offer major advantages, It has been found that electroluminescent devices produced from the solutions according to the invention in air exhibit better electroluminescence results, in particular higher efficiency, than those produced from solutions in accordance with the prior art in air. This is a surprising and unexpected result. Such solutions are thus more suitable than solutions in accordance with the prior art for producing efficient electroluminescent devices in air. The technical complexity for the production of these electroluminescent devices is thus significantly less than in accordance with the prior art, where processing of these solutions under a protective-gas atmosphere is necessary for high efficiency.

The present application text is directed, in particular, to solutions according to the invention for the production of polymeric light-emitting diodes and the corresponding displays. In spite of this restriction of the description, it is possible for the person skilled in the art, without a further inventive step, also to use corresponding solutions according to the invention for the production of other devices, for example for organic field-effect transistors (O-FETs), organic thin-film transistors (O-TFTs), organic integrated circuits (O-ICs), organic field-quench devices (O-FQDs), organic light-emitting transistors (O-LETs), light-emitting electrochemical cells (LECs), organic solar cells (O-SCs), organic laser diodes (O-lasers) or organic photoreceptors (O-PCs), to mention but a few applications.

The invention is described in greater detail below with reference to working examples, but without being restricted thereby.

### EXAMPLES 1 to 19

The polymers used are a “blue” copolymer consisting of:

50 mol % of 2′,3′,6′,7′-tetra(2-methylbutyloxy)spirobifluorene-2,7-bisboronic acid ethylene glycol ester, 30 mol % of 2,7-dibromo-2′,3′,6′,7′-tetra(2-methylbutyloxy)spirobifluorene, 10 mol % of N,N′-bis(4-bromophenyl)-N,N′-bis(4-tert-butylphenyl)benzidine and 10 mol % of 2,3,6,7-tetra(2-methyl-butyloxy)-2′,7′-(4-bromostyryl)-9,9′-spirobifluorene (P1, see also WO 03/020790),

and a “white” copolymer consisting of:

50 mol % of 2′,3′,6′,7′-tetra(2-methylbutyloxy)spirobifluorene-2,7-bisboronic acid ethylene glycol ester), 29.94 mol % of 2,7-dibromo-2′,3′,6′,7′-tetra(2-methylbutyloxy)spirobifluorene), 10 mol % of N,N′-bis(4-bromophenyl)-N,N′-bis(4-tert-butylphenyl)benzidine and 10 mol % of 2,3,6,7-tetra(2-methyl-butyloxy)-2′,7′-(4-bromostyryl)-9,9′-spirobifluorene, 0.05 mol % of i-(2-ethylhexyloxy)-4-methoxy-2,5-bis(4-bromo-2,5-dimethoxystyryl)benzene and 0.01 mol % of bis-4,7-(2′-bromo-5′-thienyl)-2,1,3-benzothiadiazole (P2, see also WO 05/030827). These are prepared by Suzuki polymerisation, as described in WO 03/048225, and have a molecular weight MW of about 500,000 g/mol (determined by GPC).

Furthermore, a “yellow” PPV comprising 50 mol % of 2,5-bis(chloromethyl)-3′-(3,7-dimethyloctyloxy)biphenyl and 50 mol % of 2,5-bis(chloromethyl)-4-methoxy-3′,4′-bis(2-methylpropyloxy)biphenyl is used (P3). The preparation of this polymer and its further properties are described in WO 99/24526.

In order to measure the ozone sensitivity, components are produced under four different conditions.
1. Under protective gas in a glove box using toluene as solvent.
2. Under protective gas in a glove box using toluene and alkene additive as solvents.
3. Under an atmosphere of 200 ppb of ozone in air produced by means of an ozone generator using toluene as solvent.
4. Under an atmosphere of 200 ppb of ozone in air produced by means of an ozone generator using toluene and alkene additive as solvents.

The ozone concentration is determined by means of an ozone measuring instrument (Anseros-LUM).

The layers are investigated for use in PLEDs. The PLEDs are each two-layer systems, i.e. substrate//ITO//PEDOT//polymer//cathode. PEDOT is a polythiophene derivative (Baytron P, from H. C. Starck, Goslar). The cathode used in all cases is Ba/Ag (Aldrich). The way in which PLEDs can be produced is described in detail in WO 04/037887 and the literature cited therein. The electro-optical characterisation and the determination of the operating lifetime are likewise carried out as described in WO 04/037887.

TABLE 1
Properties of the various polymer formulations

| | | | | Max. eff.^{b} | | | |
|---|---|---|---|---|---|---|---|
| Example | Polymer | Condition | Additive^{a} | [cd/A] | U^{c} | CIE coordinates^{d} | Lifetime^{e} |
| 1 | P1 | 1 | — | 4.0 | 4.2 | 0.18/0.26 | 2100 |
| 2 | P1 | 2 | 10% of 1-hexene | 4.1 | 4.1 | 0.18/0.26 | 2250 |
| 3 | P1 | 2 | 10% of methylcyclohexene | 4.2 | 4.1 | 0.18/0.27 | 2350 |
| 4 | P1 | 3 | — | 0.7 | 9.2 | 0.18/0.27 | <10 h |
| 5 | P1 | 4 | 10% of 1-hexene | 3.9 | 4.2 | 0.18/0.26 | 1800 |
| 6 | P1 | 4 | 10% of methylcyclohexene | 4.3 | 4.0 | 0.18/0.27 | 2500 |
| 7 | P2 | 1 | — | 7.85 | 4.1 | 0.37/0.42 | 1400 |
| 8 | P2 | 2 | 10% of methylcyclohexene | 8.0 | 4.0 | 0.37/0.41 | 1500 |
| 9 | P2 | 3 | — | 2.7 | 5.8 | 0.37/0.44 | 120 |
| 10 | P2 | 4 | 10% of methylcyclohexene | 7.6 | 4.2 | 0.37/0.41 | 1400 |
| 11 | P3 | 1 | — | 9.1 | 3.1 | 0.51/0.49 | 1100 |
| 12 | P3 | 2 | 10% of 1-hexene | 9.3 | 3.1 | 0.51/0.49 | 1200 |
| 13 | P3 | 3 | — | 2.3 | 6.3 | 0.50/0.50 | 45 |
| 14 | P3 | 4 | 1% of 1-hexene | 8.0 | 3.8 | 0.51/0.49 | 700 |
| 15 | P3 | 4 | 5% of 1-hexene | 8.9 | 3.2 | 0.51/0.49 | 1100 |
| 16 | P3 | 4 | 10% of 1-hexene | 9.2 | 3.1 | 0.51/0.49 | 1350 |
| 17 | P3 | 4 | 20% of 1-hexene | 8.5 | 3.3 | 0.51/0.49 | 1000 |
| 18 | P3 | 4 | 10% of methylcyclohexene | 9.5 | 2.9 | 0.51/0.49 | 1300 |
| 19 | P3 | 4 | 10% of 3-hexene | 8.8 | 3.3 | 0.51/0.49 | 950 |

^{a}% by vol.
^{b}Max. eff.: maximum efficiency, measured in cd/A.
^{c}Voltage at a luminance of 100 cd/m².
^{d}CIE coordinates: colour coordinates of the Commission Internationale de I'Eclairage 1931.
^{e}Lifetime: time until the luminance has dropped to 50% of the initial luminance (extrapolated to an initial luminance of 100 cd/m², in the case of P3 to 1000 cd/m²).

1-18. (canceled)

19. A single-phase solution comprising
(1) at least one organic semiconductor;
(2) at least one organic solvent for the organic semiconductor; and
(3) at least one aliphatic or cycloaliphatic alkene,
wherein the proportion of said at least one aliphatic or cycloaliphatic alkene is between 0.01 and 20% by weight, based on the solvent or solvent mixture.

20. The solution of claim 19, wherein said at least one organic semiconductor is a single component or a mixture of two or more components, at least one of which has semiconducting properties.

21. The solution of claim 19, wherein said at least one organic semiconductor is a low-molecular-weight, oligomeric, dendritic, linear or branched organic or organiometallic compound or mixture of compounds.

22. The solution of claim 19, wherein said at least one organic semiconductor is a polymeric organic or organometallic compound or mixture of compounds.

23. The solution of claim 19, wherein at least one component of said at least one organic semiconductor has high molecular weight and has a molecular weight M_{w} of greater than 10,000 g/mol.

24. The solution of claim 22, wherein said at least one organic semiconductor is selected from the group consisting of poly-p-arylenevinylenes, polyfluorenes, polyspirobifluorenes, poly-p-phenylenes or -biphenylenes, polydihydrophenanthrenes, trans- and cis-polyindenofluorenes, polyphenanthrenes, polythiophenes, polypyridines, polypyrroles, polyvinylcarbazoles, triarylamine polymers, polysilylenes, polygermylenes, polymers containing phosphorescent units, and copolymers thereof, all of which are optionally substituted and are soluble in organic solvents.

25. The solution of claim 19, wherein said solutions comprise between 0,01 and 20% by weight of said at least one organic semiconductor.

26. The solution of claim 19, wherein said solvents used are mono- or polysubstituted aromatic solvents, formic acid derivatives, N-alkylpyrrolidones or high-boiling ethers and/or mixtures with straight-chain, branched or cyclic alkanes, (cyclo)aliphatic alcohols, ethers, ketones or carboxylic acid esters.

27. The solution of claim 19, wherein the boiling point of said at least one aliphatic or cycloaliphatic alkene is below 250° C.

28. The solution of claim 19, wherein the boiling point of said at least one aliphatic or cycloaliphatic alkene is above 50° C.

29. The solution of claim 19, wherein said at least one aliphatic or cycloaliphatic alkene contain 5 to 15 carbon atoms.

30. The solution of claim 19, wherein said at least one aliphatic or cycloaliphatic alkene are selected from the group consisting of 2,3-dimethyl-2-butene, 4-methyl-1-pentene, 2,3-dimetlhyl-1-butene, 1,5-hexadiene, 1-hexene, 1-methyl-1-cyclopentene, 1,3-cyclohexadiene, cyclohexene, trans,trans-2,4-hexadiene, 1,4-cyclohexadiene, 2-methyl-1-hexene, 1-heptene, 2,4,4-trimethyl-1-pentene, 1,7-octadiene, 1-octene, trans-4-octene, trans-2-octene, 1,3-cyclooctadiene, styrene, dicyclopentadiene, 1,9-decadiene, 1-decene, 1-dodecene, cyclododecene, 2,5-dimethyl-2,4-hexadiene, 1-tridecene and cis,trans,tranis-1,5,9-cyclododecatriene.

31. A process for producing organic semiconductor layers on a substrate, comprising processing the solution of claim 19 by means of a printing process or an area-coating process.

32. An organic semiconductor layer produced using the solution of claim 19.

33. An organic semiconductors layer produced by the process of claim 31.

34. An article comprising the organic semiconductors layer of claim 33, wherein said article is selected from the group consisting of organic or polymeric light-emitting diodes, organic field-effect transistors, organic thin-film transistors, organic integrated circuits, organic field-quench devices, organic light-emitting transistors, light-emitting electrochemical cells, organic solar cells, organic laser diodes, and organic photo receptors.

35. An organic or polymeric light-emitting diode, organic field-effect transistor, organic thin-film transistor, organic integrated circuit, organic field-quench device, organic light-emitting transistor, light-emitting electrochemical cell, organic solar cell, organic laser diode, or organic photo receptor comprising at least one organic semiconductor layer of claim 32.

36. A display comprising the organic or polymeric light-emitting diode of claim 35.
